(19) United States
(12) Patent Application Publication
(10) Pub. No.: US 2016/0343514 A1
(43) Pub. Date: Nov. 24, 2016

(54) PHOTOVOLTAIC DEVICE COMPRISING POROUS TITANIUM OXIDE LAYER, FIRST HOLE TRANSPORT LAYER, AND SECOND HOLE TRANSPORT LAYER

(71) Applicant: Panasonic Corporation, Osaka (JP)

(72) Inventors: RYUSUKE UCHIDA, Osaka (JP); MICHIO SUZUKA, Osaka (JP); TAKASHI SEKIGUCHI, Osaka (JP)

(21) Appl. No.: 15/153,429

(22) Filed: May 12, 2016

(30) Foreign Application Priority Data
May 19, 2015 (JP) 2015-101860

(51) Int. Cl. H01G 9/20; H01L 51/00

(52) U.S. Cl. CPC H01G 9/2018; H01G 9/2031; H01G 9/2059; H01L 51/0072; H01L 51/0069; H01L 51/0083; H01L 51/0035; H01L 51/0067

(57) ABSTRACT

A photovoltaic device according to an aspect of the present disclosure includes a first electrode, a second electrode positioned to face the first electrode, a porous titanium oxide layer on a surface of the first electrode facing the second electrode, a first hole transport layer between the porous titanium oxide layer and the second electrode, and a second hole transport layer between the first hole transport layer and the second electrode. The porous titanium oxide layer contains a porous titanium oxide that supports a photosensitizer. The first hole transport layer contains a first redox substance. The second hole transport layer contains a second redox substance. The second redox substance has a redox potential more negative than that of the first redox substance by 0.5 V or more.

### BACKGROUND

1. Technical Field

The present disclosure relates to photovoltaic devices, which are devices that convert light into electricity.

2. Description of the Related Art

In recent years, equipment such as sensors for temperature, light and so forth incorporate photovoltaic devices. For solar cells, which represent a type of photovoltaic devices, pn junction devices have been in practical use, and dye-sensitized devices are under active research.

The dye-sensitized photovoltaic device described in Japanese Patent No. 2664194 has a semiconductor, a charge transport layer, a first electrode to which the semiconductor has been attached, and a second electrode. When the device is illuminated with light, charge generated in the semiconductor travels through the charge transport layer, and the user can take out electricity using the first and second electrodes as an anode and a cathode, respectively.

A problem with this photovoltaic device is that shielding the light leads to an immediate drop of voltage. As a solution to this problem, researchers have proposed photovoltaic devices electrically coupled to storage batteries such as that described in Japanese Unexamined Patent Application Publication No. 2009-81046. Such devices are, unfortunately, thick and heavy because of the storage and generator batteries they have.

### SUMMARY

In one general aspect, the techniques disclosed here feature a photovoltaic device that includes a first electrode, a second electrode positioned to face the first electrode, a porous titanium oxide layer on the surface of the first electrode facing the second electrode, a first hole transport layer between the porous titanium oxide layer and the second electrode, and a second hole transport layer between the first hole transport layer and the second electrode. The porous titanium oxide layer contains a porous titanium oxide that supports a photosensitizer. The first hole transport layer contains a first redox substance. The second hole transport layer contains a second redox substance. The second redox substance has a redox potential more negative than that of the first redox substance by 0.5 V or more.

The photovoltaic device according to the present disclosure offers the capability of storing electricity in a simple configuration.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a schematic cross-sectional view of a photovoltaic device according to a first embodiment of the present disclosure;

FIG. 2 is a schematic cross-sectional view of a variation of the photovoltaic device according to the first embodiment;

FIG. 3 is a schematic cross-sectional view of a photovoltaic device according to a second embodiment of the present disclosure; and

FIG. 4 is a schematic cross-sectional view of a photovoltaic device according to a third embodiment of the present disclosure.

### DETAILED DESCRIPTION

The present disclosure includes photovoltaic devices described under the following items.

### Item 1

A photovoltaic device comprising:
a first electrode;
a second electrode positioned to face the first electrode;
a porous titanium oxide layer on a surface of the first electrode facing the second electrode, the porous titanium oxide layer containing a porous titanium oxide supporting a photosensitizer;
a first hole transport layer between the porous titanium oxide layer and the second electrode, the first hole transport layer containing a first redox substance; and
a second hole transport layer between the first hole transport layer and the second electrode, the second hole transport layer containing a second redox substance, wherein
the second redox substance has a redox potential more negative than a redox potential of the first redox substance by 0.5 V or more.

### Item 2

The photovoltaic device according to item 1, wherein the first hole transport layer is liquid.

### Item 3

The photovoltaic device according to item 1 or 2, wherein the first redox substance is 2,2,6,6-tetramethylpiperidine 1-oxyl.

### Item 4

The photovoltaic device according to any one of items 1 to 3, wherein the redox potential of the second redox substance is in a range of −0.2 V to 0 V relative to an Ag/Ag⁺ electrode at 25° C.

### Item 5

The photovoltaic device according to any one of items 1 to 4, further comprising a third hole transport layer between the first and second hole transport layers, the third hole transport layer containing a third redox substance, wherein the third redox substance has a redox potential more negative than the redox potential of the first redox substance and more positive than the redox potential of the second redox substance.

### Item 6

The photovoltaic device according to any one of items 1 to 5, further comprising:
a third electrode electrically connected to the first electrode; and
an electron accumulation layer in contact with the third electrode, the electron accumulation layer containing a fourth redox substance.

### Item 7

The photovoltaic device according to any one of items 1 to 5, further comprising an electron accumulation layer disposed on the surface of the first electrode and spaced from the porous titanium oxide layer, the electron accumulation layer containing a fourth redox substance.

The following describes some embodiments of the present disclosure with reference to the attached drawings.

### First Embodiment

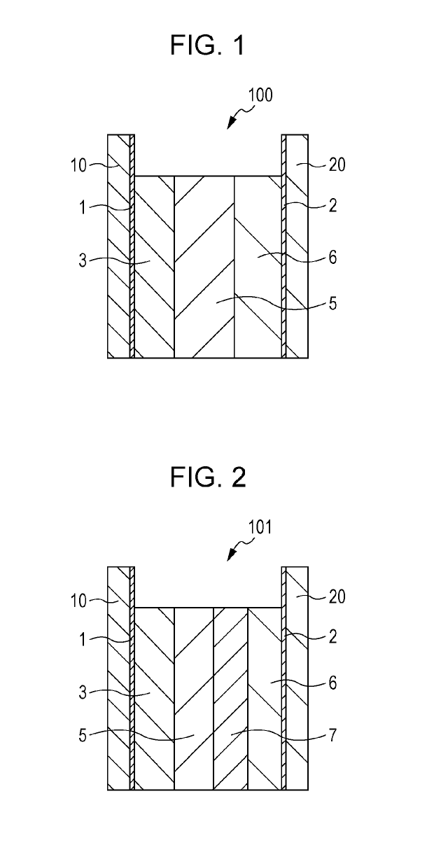

A photovoltaic device 100 according to this embodiment has, as illustrated in FIG. 1, a first electrode 1, a porous titanium oxide layer 3, a first hole transport layer 5, a second hole transport layer 6, and a second electrode 2. The first hole transport layer 5 contains a first redox substance, and the second hole transport layer 6 contains a second redox substance. The first electrode 1 and the second electrode 2 are positioned to face each other. The porous titanium oxide layer 3 is on the surface of the first electrode 1 facing the second electrode 2, and contains a porous titanium oxide that supports a photosensitizer. The second hole transport layer 6 is between the first hole transport layer 5 and the second electrode 2. The second redox substance, contained in the second hole transport layer 6, has a redox potential more negative than that of the first redox substance, contained in the first hole transport layer 5, by 0.5 V or more.

The photovoltaic device 100 may have a first substrate 10 and a second substrate 20. In such a case, the first electrode 1 and the second electrode 2 are disposed on the first substrate 10 and the second substrate 20, respectively, as in FIG. 1.

The following describes the key operations and advantages of the photovoltaic device 100 according to this embodiment.

When the photovoltaic device 100 is illuminated with light, the photosensitizer supported by the porous titanium oxide layer 3 absorbs the light, generating electrons in the excited state and holes. The excited electrons move to the porous titanium oxide. The holes, generated at the photosensitizer, move to the first hole transport layer 5. The holes then leave the first hole transport layer 5 and travel to the second hole transport layer 6 with a high degree of probability. Since the porous titanium oxide layer 3 is coupled to the first electrode 1 and the second hole transport layer 6 is coupled to the second electrode 2, the user can take electric current out of the photovoltaic device 100 using the first electrode 1 and the second electrode 2 as an anode and a cathode, respectively.

The reason for the highly probable movement of holes from the first hole transport layer 5 to the second hole transport layer 6 is that the redox potential of the second redox substance, contained in the second hole transport layer 6, is more negative than that of the first redox substance, contained in the first hole transport layer 5, by 0.5 V or more. The photovoltaic device 100 is able to store electrons and holes in separate spaces, i.e., the porous titanium oxide layer 3 and the second hole transport layer 6. In the photovoltaic device 100, therefore, the recombination of electrons and holes is limited. As a result, the photovoltaic device 100 offers the capability of storing photovoltaic electricity without needing a separate storage battery coupled thereto.

The configuration in which porous titanium oxide supports a photosensitizer provides interfaces for the photosensitizer to perform light-induced charge separation, leading to an improved photovoltaic efficiency.

FIG. 2 is a schematic cross-sectional view of a variation of the photovoltaic device according to this embodiment. The photovoltaic device 101 illustrated in FIG. 2 has a third hole transport layer 7 between the first hole transport layer 5 and the second hole transport layer 6. The third hole transport layer 7 contains a third redox substance that has a redox potential more negative than that of the first redox substance and more positive than that of the second redox substance. In a device that has a third hole transport layer 7, holes pass through the third hole transport layer 7 while moving from the first hole transport layer 5 to the second hole transport layer 6. This leads to a greater spatial separation between the porous titanium oxide layer 3, in which electrons accumulate, and the second hole transport layer 6 than in the photovoltaic device 100, further limiting the recombination of electrons and holes.

The fabrication of the photovoltaic device 100 according to this embodiment can be, for example, as follows. First, a first electrode 1 is formed on the surface of a first substrate 10. A porous titanium oxide layer 3 is formed on the first electrode 1 using coating or similar techniques. The first substrate 10 is then immersed in a solution containing a photosensitizer to immobilize the photosensitizer in the porous titanium oxide.

A second electrode 2 is formed on the surface of a second substrate 20. A second hole transport layer 6 is formed on the second electrode 2 using drop casting or similar techniques.

After a sealant is applied around the second hole transport layer 6 on the second electrode 2 on the second substrate 20, the first substrate 10 and the second substrate 20 are bonded together. Then, for example, a solution containing a first redox substance is injected through an opening created in the sealant, and the opening is closed to form a first hole transport layer 5. Through this process, the photovoltaic device 100 is obtained.

The following provides further details of the individual components of the photovoltaic device 100.

The first substrate 10, which is an optional component, is permeable to light. The second substrate 20 may be impermeable to light. Each of the first substrate 10 and the second substrate 20 can be, for example, a glass or plastic substrate (or plastic film) that allows visible light to pass through.

The first electrode 1 is conductive, and permeable to light. The first electrode 1 may be integral with the first substrate 10. In such a case, the first electrode 1 is formed of a light-permeable material. Examples of such materials include transparent and conductive metal oxides, such as indium tin oxide, antimony-doped tin oxide, and fluorine-doped tin oxide, and composites of such compounds. Alternatively, the first electrode 1 may be disposed on the first substrate 10. For example, the first electrode 1 can be a film or a stack of multiple layers on the first substrate 10. In such a case, the first electrode 1 may be formed of a light-permeable material, such as one of the materials listed above.

The first electrode 1 may be formed of a material impermeable to light. For example, the use of a patterned first electrode 1, or an electrode having empty areas, will ensure permeation of light. Examples of possible patterns include stripes, corrugations, mesh, and punched metal, which means a regular or irregular arrangement of a number of small through-holes. Examples of materials impermeable to light include metals such as platinum, gold, silver, copper, aluminum, rhodium, and indium, carbon, and conductive metal oxides. A first electrode 1 made of a compound with a high electron mobility may be coated with a material that prevents leakage of electrons from the surface, or a rectifying material, such as silicon oxide, tin oxide, titanium oxide, zirconium oxide, or aluminum oxide.

The amount of light the device takes in, and therefore the electrical efficiency of the device, increase with increasing optical transmittance of the first electrode 1. The optical transmittance of the first electrode 1 can be 50% or more, and can even be 80% or more. The thickness of the first electrode 1 can be in the range of 1 to 100 nm. The first electrode 1 can be formed with high thickness uniformity and preserved optical transmission, allowing a sufficient amount of light to come into the porous titanium oxide layer 3, when its thickness is in this range.

The second electrode 2 is conductive. The second electrode 2 may be integral with the second substrate 20. To serve efficiently as a cathode of the photovoltaic device 100, the second electrode 2 may contain a catalyst that donates electrons to the reductant contained in the second hole transport layer 6. Examples of materials for the second electrode 2 include metals such as platinum, gold, silver, copper, aluminum, rhodium, and indium, carbon materials such as graphite, carbon nanotubes, and platinum on carbon, conductive metal oxides such as indium tin oxide, antimony-doped tin oxide, and fluorine-doped tin oxide, and conductive polymers such as polyethylenedioxythiophene, polypyrrole, and polyaniline. Among these, the material for the second electrode 2 may be selected from the group consisting of platinum, graphite, and polyethylenedioxythiophene.

The porous titanium oxide layer 3 may have a thickness of 0.01 to 100 μm. This layer provides a sufficient photovoltaic effect and maintains good permeability to visible and near-infrared light when its thickness is in this range. The thickness of the porous titanium oxide layer 3 can be in the range of 0.5 to 50 μm, and can even be in the range of 1 to 20 μm.

The formation of the porous titanium oxide layer 3 is as follows. A solution containing a titanium oxide powder and an organic binder, such as an organic solvent, is applied to the surface of the first electrode 1 using, for example, a coating technique that utilizes a doctor blade, a bar coater, or similar, spraying, dip coating, screen printing, or spin coating. The organic binder is then removed through a process such as heating and firing or pressing in a press machine. This yields the porous titanium oxide layer 3.

The surface roughness of the porous titanium oxide layer 3 can be 10 or more. The surface roughness as mentioned herein is the effective area divided by the projected area. The projected area of an object is the area of the shadow that appears behind the object when frontal lighting shines on the object. The effective area of an object is the actual surface area of the object and can be calculated from the volume of the object and the specific surface area and bulk density of the material of which the object is made. The volume of the object can be determined from the projected area and thickness of the object. A surface roughness of 10 or more leads to a large surface area of the interfaces for light-induced charge separation and therefore to improved photovoltaic properties. The surface roughness can be in the range of 100 to 2000.

The photosensitizer can be an inorganic material, such as ultrafine particles of a semiconductor, or an organic material, such as a dye or a pigment. For efficient light absorption and charge separation, the photosensitizer can be a dye. Examples of dyes that can be used include 9-phenyl xanthene dyes, coumarin dyes, acridine dyes, triphenylmethane dyes, tetraphenylmethane dyes, quinone dyes, azo dyes, indigo dyes, cyanine dyes, merocyanine dyes, and xanthene dyes. Other dyes can also be used, including ruthenium-cis-diaqua-bipyridyl complexes of a type of RuL₂(H₂O)₂ (where L represents 4,4′-dicarboxy-2,2′-bipyridine), transition metal complexes of types such as ruthenium-tris (RuL₃), ruthenium-bis (RuL₂), osmium-tris (OsL₃), and osmium-bis (OsL₂), zinc-tetra(4-carboxyphenyl)porphyrin, iron-hexacyanide complexes, and phthalocyanine. The dyes mentioned in a section about DSSC of a book in Japanese about “the cutting-edge technologies and material development concerning FPD, DSSC, optical memories, and functional dyes” (NTS Inc.) can also be used. In particular, dyes that are associative on the porous titanium oxide layer 3 serve as an insulator by densely packing and covering the surface of the porous titanium oxide layer 3. When the photosensitizer serves as an insulator, the flow of generated electrons is rectified at the charge separation interfaces and, as a result, the recombination of separated charge is reduced. This makes the photovoltaic device an even more efficient converter.

An example of a method for immobilizing the photosensitizer in the porous titanium oxide layer 3 is to immerse the first substrate 10 after the formation of the first electrode 1 and the attachment of the porous titanium oxide layer 3 into a solution or dispersion of the photosensitizer. The solvent of the solution can be of any kind in which the photosensitizer is soluble, including water, alcohols, toluene, and dimethylformamide. The solution of the photosensitizer may be heated to reflux or sonicated while the porous titanium oxide layer 3 is immersed therein for a certain period of time. After the immobilization of the photosensitizer, the porous titanium oxide layer 3 may be washed with an alcohol or heated to reflux to remove the residual, unsupported photosensitizer.

The amount of photosensitizer supported by the porous titanium oxide layer 3 can be in the range of 1×10⁻¹⁰ to 1×10⁻⁴ mol/cm², and can even be in the range of 0.1×10⁻⁸ to 9.0×10⁻⁶ mol/cm². The use of the photosensitizer in an amount in this range leads to an economical and sufficient improvement in photovoltaic efficiency.

Each of the first hole transport layer 5 and the second hole transport layer 6 contains a redox substance, and is a liquid or solid layer. When the first hole transport layer 5 is a liquid layer and the second hole transport layer 6 is a solid layer, there may be a separator in the first hole transport layer 5 to prevent the photosensitizer in the porous titanium oxide layer 3 from coming into contact with the second hole transport layer 6. The separator can be, for example, a sheet of cellulose, a porous plastic film, or a non-woven plastic sheet.

The term “redox substance” refers to a substance that reversibly switches between oxidant and reductant forms through a redox reaction. Examples of oxidant-reductant couples that can be used include, but are not limited to, a chlorine compound-chlorine, an iodine compound-iodine, a bromine compound-bromine, thallium(III) ion-thallium(I) ion, mercury(II) ion-mercury(I) ion, ruthenium(III) ion-ruthenium(II) ion, copper(II) ion-copper(I) ion, iron(III) ion-iron(II) ion, nickel(III) ion-nickel (II) ion, vanadium(III) ion-vanadium(II) ion, and manganate ion-permanganate ion. Other examples of usable redox substances include 2,2,6,6-tetramethylpiperidine 1-oxyl (TEMPO), ferrocenes having multiple (2 to 10) methyl substituents and their polymers, and phenothiazines and their polymers.

The redox substances contained in the first hole transport layer 5 and the second hole transport layer 6 may have the ability to undergo the redox reaction at a constant voltage. For example, if the voltage drop after repeating charge and discharge cycles at a rate of 1 C until a capacity of 50% is 0.3 V or less, the redox substance can be regarded as being able to undergo the redox reaction at a constant voltage. Such a redox substance allows the photovoltaic device 100 to discharge at a constant voltage, ensuring consistent power supply to equipment. Examples of redox substances having this constant-voltage redox capability include polymers having a redox substance in their side chains or backbones and gels formed using a gelling agent.

Examples of redox substances that do not have the constant-voltage redox capability include those that store and release charge through doping and dedoping, such as PEDOT-PSS and polypyrrole, and those that are intercalated into an oxide, such as lithium cobaltate.

When the first hole transport layer 5 or the second hole transport layer 6 is a liquid layer, this liquid layer contains a solvent, a supporting salt (supporting electrolyte), and a redox substance. Examples of supporting salts that can be used include tetrabutylammonium perchlorate, tetraethylammonium hexafluorophosphate, ammonium salts such as imidazolium salts and pyridinium salts, and alkali metal salts such as lithium perchlorate and potassium tetrafluoroborate.

The solvent in the liquid layer may be a highly ion conductive compound, and can be an aqueous or organic solvent. The use of an organic solvent leads to higher stability of the redox substance. Examples of organic solvents that can be used include carbonate compounds such as dimethyl carbonate, diethyl carbonate, methyl ethyl carbonate, ethylene carbonate, and propylene carbonate, ester compounds such as methyl acetate, methyl propionate, and y-butyrolactone, ether compounds such as diethyl ether, 1,2-dimethoxyethane, 1,3-dioxolane, tetrahydrofuran, and 2-methyl-tetrahydrofuran, heterocyclic compounds such as 3-methyl-2-oxazolidinone and 2-methylpyrrolidone, nitrile compounds such as acetonitrile, methoxyacetonitrile, and propionitrile, and aprotic polar compounds such as sulfolane, dimethylsulfoxide, and dimethylformamide. These solvents can be used alone or in a mixture of two or more. The solvent in the liquid layer can be a carbonate compound such as ethylene carbonate or propylene carbonate, a heterocyclic compound such as 3-methyl-2-oxazolidinone or 2-methylpyrrolidone, or a nitrile compound such as acetonitrile, methoxyacetonitrile, propionitrile, 3-methoxypropionitrile, or valeronitrile.

The solvent in the liquid layer can also be an ionic liquid, alone or mixed with any other solvent. The use of an ionic liquid leads to particularly high stability of the redox substance. Ionic liquids are highly stable because of their non-volatility and high flame retardancy. Furthermore, ionic liquids are able to act as supporting salts, and the use of an ionic liquid as the solvent eliminates the need for the supporting salt. Any known ionic liquid can be used, and examples include imidazolium-based ionic liquids such as 1-ethyl-3-methylimidazolium tetracyanoborate, pyridine-based, alicyclic amine-based, aliphatic amine-based, and azonium amine-based ionic liquids, and the ionic liquids mentioned in European Patent No. 718288, International Publication No. 95/18456, Electrochemistry Vol. 65, No. 11, page 923 (1997), J. Electrochem. Soc. Vol. 143, No. 10, page 3099 (1996), and Inorg. Chem. Vol. 35, page 1168 (1996).

When the first hole transport layer 5 or the second hole transport layer 6 is a solid layer, its formation is as follows. A solution containing a redox substance, a binder, and a solvent is applied to the first electrode 1 or the second electrode 2 using, for example, a coating technique that utilizes a doctor blade, a bar coater, or similar, spraying, dip coating, screen printing, or spin coating. The solvent is then removed through a process such as heating and firing or pressing in a press machine. This yields a solid layer in which the binder supports the redox substance. Specific examples of binders that can be used include electrolyte gels and polymer electrolytes. Electrolyte gels can be obtained by mixing a gelling agent in an electrolytic solution. Examples of usable gelling agents include polymers, gelling agents whose action is based on polymer crosslinking, gelling agents that contain a polymerizable polyfunctional monomer, and oil-gelling agents. Examples of polymer electrolytes that can be used include vinylidene fluoride polymers such as polyvinylidene fluoride, acrylic acid polymers such as polyacrylic acid, acrylonitrile polymers such as polyacrylonitrile, polyethers such as polyethylene oxide, and compounds having an amide moiety in their molecular structures.

When the first hole transport layer 5 or the second hole transport layer 6 is a solid layer, furthermore, this solid layer may contain a conductive agent. Mixing the redox substance with a conductive agent reduces the internal resistance of the solid layer. Examples of conductive agents that can be used include carbon black, graphite, and carbon fiber.

The first redox substance, contained in the first hole transport layer 5, has a redox potential more positive than −0.7 V (vs. Ag/Ag⁺) (an RE-7 reference electrode; BAS Inc.), the level of the conduction band of the porous titanium oxide layer 3.

The second redox substance, contained in the second hole transport layer 6, has a redox potential more negative than that of the first redox substance, contained in the first hole transport layer 5, by 0.5 V or more.

When the first hole transport layer 5 contains TEMPO, which is a redox substance and has a redox potential of +0.5 V (vs. Ag/Ag⁺), the redox potential of the second redox substance, contained in the second hole transport layer 6, can be in the range of −0.2 to 0 V (vs. Ag/Ag⁺), and can even be in the range of −0.1 to 0 V (vs. Ag/Ag⁺). The output from the photovoltaic device 100 increases with increasing difference between the level of the conduction band of the porous titanium oxide layer 3 and the redox potential of the second hole transport layer 6. Thus, when the second redox substance, contained in the second hole transport layer 6, has a redox potential of −0.2 to 0 V (vs. Ag/Ag⁺), the second hole transport layer 6 is able to store holes without affecting the voltage the photovoltaic device 100 produces. The second redox substance, contained in the second hole transport layer 6, can be, for example, a ferrocene having multiple (e.g., 2 to 10) methyl substituents or its polymer or a phenothiazine or its polymer.

The thickness of the second hole transport layer 6 is not designated. It can be in the range of 0.1 μm to 1000 μm, and can even be in the range of approximately 1 μm to 100 μm. The whole of the second hole transport layer 6 can be used for power generation while maintaining the charging capacity when the thickness of this layer is in this range.

### Second Embodiment

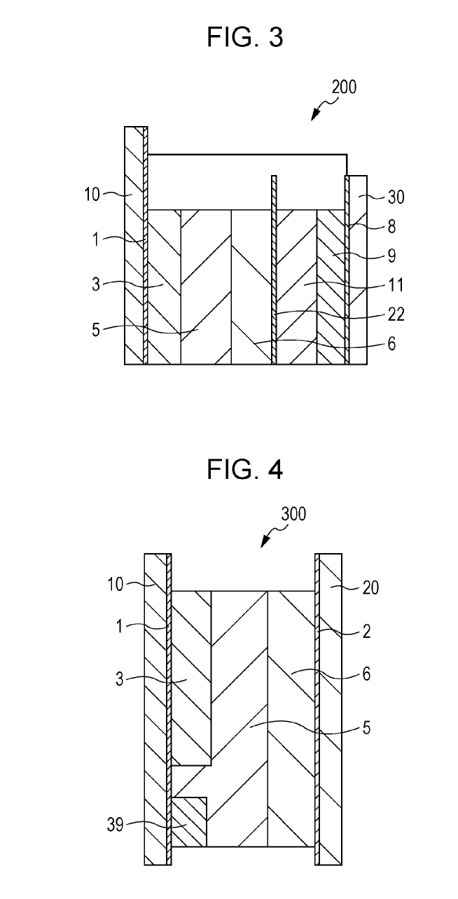

The following describes a photovoltaic device 200 according to a second embodiment of the present disclosure with reference to FIG. 3.

The difference of the photovoltaic device 200 according to this embodiment from the photovoltaic device 100 according to the first embodiment lies in the presence of a third electrode 8 and an electron accumulation layer 9 and the configuration of the second electrode.

In the following, any component of the photovoltaic device 200 equivalent in terms of function and configuration to one described in the context of the photovoltaic device 100 is referenced by the same numeral as for the photovoltaic device 100 without repeating the description.

As illustrated in FIG. 3, the photovoltaic device 200 has a first electrode 1, a second electrode 22, a porous titanium oxide layer 3, a first hole transport layer 5, a second hole transport layer 6, a third electrode 8, and an electron accumulation layer 9. The porous titanium oxide layer 3 supports a photosensitizer. The third electrode 8 is electrically connected to the first electrode 1. The electron accumulation layer 9 contains a fourth redox substance and is disposed on the third electrode 8.

The photovoltaic device 200 may have a first substrate 10 and a second substrate 30. In such a case, the first electrode 1 and the third electrode 8 are disposed on the first substrate 10 and the second substrate 30, respectively.

The following describes the key operations and advantages of the photovoltaic device 200 according to this embodiment.

When the photovoltaic device 200 is illuminated with light, the photosensitizer supported by the porous titanium oxide layer 3 absorbs the light, generating electrons in the excited state and holes. The excited electrons move to the porous titanium oxide. The electrons then leave the porous titanium oxide and travel to the first electrode 1, and to the electron accumulation layer 9 via the third electrode 8, which is electrically connected to the first electrode 1. The holes, generated at the photosensitizer, move to the first hole transport layer 5. The holes then leave the first hole transport layer 5 and travel to the second hole transport layer 6 with a high degree of probability. Since the electron accumulation layer 9 is coupled to the third electrode 8 and the second hole transport layer 6 to the second electrode 22, the user can take electric current out of the photovoltaic device 200 using the third electrode 8 and the second electrode 22 as an anode and a cathode, respectively. The photovoltaic device 200 is able to store electrons and holes in separate spaces, i.e., the electron accumulation layer 9 and the second hole transport layer 6. The recombination of electrons and holes is therefore limited. As a result, the photovoltaic device 200 offers the capability of storing electricity without needing a separate storage battery coupled thereto.

The fabrication of the photovoltaic device 200 according to this embodiment can be, for example, as follows. First, a first electrode 1 is formed on the surface of a first substrate 10. A porous titanium oxide layer 3 is formed on the first electrode 1 using coating or similar techniques. The first substrate 10 is then immersed in a solution containing a photosensitizer to immobilize the photosensitizer in the porous titanium oxide.

A third electrode 8 is formed on the surface of a second substrate 30. An electron accumulation layer 9 is formed on the third electrode 8 using drop casting or similar techniques.

A second hole transport layer 6 is formed on the second electrode 22 using drop casting or similar techniques.

A sealant is applied around the porous titanium oxide layer 3 on the first electrode 1 on the first substrate 10 and around the electron accumulation layer 9 on the third electrode 8 on the second substrate 30. The first substrate 10 and the second substrate 30 are then bonded together with the second hole transport layer 6 and the porous titanium oxide layer 3 facing each other, and with the second electrode 22 between the two substrates. Then, for example, a solution containing a first redox substance is injected through an opening created in the sealant between the first electrode 1 and the second electrode 22 to form a first hole transport layer 5. The material for a liquid layer 11 is then injected through an opening created in the sealant between the second electrode 22 and the third electrode 8 to form a liquid layer 11. Through this process, the photovoltaic device 200 is obtained.

The following provides further details of the individual components of the photovoltaic device 200, excluding those the photovoltaic device 100 also has.

For the second substrate 30, which is an optional component, possible configurations are similar to those for the first substrate 10 and the second substrate 20.

The third electrode 8 is spaced from the second electrode 22. The configuration of the third electrode 8 can be the same as that of the first electrode 1 or the second electrode 2.

The electron accumulation layer 9 can be configured in the same way as the first hole transport layer 5 or the second hole transport layer 6. There is a spatial separation between the electron accumulation layer 9 and the second hole transport layer 6.

The second electrode 22, for which usable materials are similar to those for the second electrode 2, has through-holes that allow the solvent in the first hole transport layer 5 to pass through. Examples of such second electrodes 22 include a mesh electrode such as platinum mesh, a grid electrode, an electrode composed of a separator and a conductive layer thereon formed by sputtering or vapor deposition of gold, platinum, or similar, and a porous piece of a conductive material.

The space between the second electrode 22 and the electron accumulation layer 9 is filled with the liquid layer 11. The liquid layer 11 contains a solvent and a supporting salt and a redox substance dissolved in the solvent. Materials that can be used as the solvent, the supporting salt, and the redox substance are similar to those that can be used in the first hole transport layer 5 and the second hole transport layer 6.

### Third Embodiment

The following describes a photovoltaic device 300 according to a third embodiment of the present disclosure with reference to FIG. 4.

The difference of the photovoltaic device 300 according to this embodiment from the photovoltaic device 100 according to the first embodiment lies in the presence of an electron accumulation layer 39.

In the following, any component of the photovoltaic device 300 equivalent in terms of function and configuration to one described in the context of the photovoltaic device 100 is referenced by the same numeral as for the photovoltaic device 100 without repeating the description.

As illustrated in FIG. 4, the photovoltaic device 300 has a first electrode 1, a second electrode 2, a porous titanium oxide layer 3, a first hole transport layer 5, a second hole transport layer 6, and an electron accumulation layer 39. The porous titanium oxide layer 3 supports a photosensitizer. The electron accumulation layer 39 contains a fourth redox substance. The porous titanium oxide layer 3 and the electron accumulation layer 39 are disposed on the first electrode 1, spaced from each other.

The photovoltaic device 300 may have a first substrate 10 and a second substrate 20. In such a case, the first electrode 1 and the second electrode 2 are disposed on the first substrate 10 and the second substrate 20, respectively.

The following describes the key operations and advantages of the photovoltaic device 300 according to this embodiment.

When the photovoltaic device 300 is illuminated with light, the photosensitizer supported by the porous titanium oxide layer 3 absorbs the light, generating electrons in the excited state and holes. The excited electrons move to the porous titanium oxide. The electrons then leave the porous titanium oxide and travel to the electron accumulation layer 39 via the first electrode 1. The holes, generated at the photosensitizer, move to the first hole transport layer 5. The holes then leave the first hole transport layer 5 and travel to the second hole transport layer 6 with a high degree of probability. Since the electron accumulation layer 39 is coupled to the first electrode 1 and the second hole transport layer 6 is coupled to the second electrode 2, the user can take electric current out of the photovoltaic device 300 using the first electrode 1 and the second electrode 2 as an anode and a cathode, respectively.

The photovoltaic device 300 is able to store electrons and holes in separate spaces, i.e., the electron accumulation layer 39 and the second hole transport layer 6. The recombination of electrons and holes is therefore limited. As a result, the photovoltaic device 300 offers the capability of storing electricity without needing a separate storage battery coupled thereto.

The fabrication of the photovoltaic device 300 according to this embodiment can be, for example, as follows.

First, a first electrode 1 is formed on the surface of a first substrate 10. A porous titanium oxide layer 3 is formed on the first electrode 1 using coating or similar techniques. An electron accumulation layer 39 is formed on the first electrode 1 using drop casting or similar techniques, spaced from the porous titanium oxide layer 3. The first substrate 10 is then immersed in a solution containing a photosensitizer to immobilize the photosensitizer in the porous titanium oxide, but in such a way that the electron accumulation layer 39 does not come into contact with the solution.

A second electrode 2 is formed on the surface of a second substrate 20. A second hole transport layer 6 is formed on the second electrode 2 using drop casting or similar techniques.

After a sealant is applied around the second hole transport layer 6 on the second electrode 2 on the second substrate 20, the first substrate 10 and the second substrate 20 are bonded together. Then, for example, a solution containing a first redox substance is injected through an opening created in the sealant to form a first hole transport layer 5. Through this process, the photovoltaic device 300 is obtained.

Possible configurations for the electron accumulation layer 39 are similar to those for the first hole transport layer 5 or the second hole transport layer 6.

### EXAMPLES

The following describes the above embodiments of the present disclosure in further detail by providing some examples. Photovoltaic devices of Examples 1 to 5 and Comparative Examples 1 to 3 were fabricated and evaluated for their characteristics. Table 1 summarizes the results.

### Example 1

A photovoltaic device having the same configuration as the photovoltaic device 100 in FIG. 1 was fabricated. The components used were as follows.
First electrode 1: Fluorine-doped SnO₂
Second electrode 2: Fluorine-doped SnO₂ and platinum
Photosensitizer: MD153 (Mitsubishi Paper Mills)
First redox substance: TEMPO
Second redox substance: Polydecamethylferrocene (PDMFc)

The fabrication of the photovoltaic device of Example 1 was as follows.

A 1 mm thick glass substrate (Asahi Glass) as a first substrate 10 was prepared having a fluorine-doped SnO₂ layer as a first electrode 1 thereon. The surface resistance of the first electrode 1 was 10Ω/square. An approximately 10 nm thick titanium oxide layer was attached to the surface of the first electrode 1 using sputtering. A high-purity titanium oxide powder having an average primary particle diameter of 20 nm was dispersed in ethyl cellulose, and the resulting paste for screen printing was applied to the titanium oxide layer and dried. The obtained dry material was fired in air at 450° C. for 30 minutes to form a 5 μm thick porous titanium oxide layer 3 (titanium coating) on the first electrode 1. The surface roughness of this porous titanium oxide layer 3 was approximately 250.

The first substrate 10, having this porous titanium oxide layer 3 thereon, was immersed in a 0.3 mM solution of the photosensitizing dye represented by chemical formula (1) (MD153; Mitsubishi Paper Mills) in a 1:1 mixture of acetonitrile and butanol. This solution was allowed to stand in the dark at room temperature for 3 hours to immobilize the photosensitizer in the porous titanium oxide layer 3.

A 1 mm thick glass substrate (Asahi Glass) as a second substrate 20 was prepared having a fluorine-doped SnO₂ layer thereon. The surface resistance of the fluorine-doped SnO₂ layer was 10Ω/square. A layer of platinum was formed on the surface of the fluorine-doped SnO₂ layer using sputtering, completing a second electrode 2. Then 2 mg of the PDMFc represented by chemical formula (2), 8 mg of a carbon fiber material (Showa Denko) as a conductive agent, and 0.01 mg of polyvinylidene fluoride (PVDF) as a binder were mixed with 0.1 ml of n-methylpyrrolidone (NMP), and the resulting slurry was applied to the platinum layer of the second electrode 2 using drop casting to form a second hole transport layer 6.

A hot-melt adhesive (DuPont-Mitsui Polychemicals) as a sealant was placed on the second electrode 2 in a shape such that bonding the first electrode 1 and the second electrode 2 together would make the porous titanium oxide layer 3 portion of the first electrode 1 enclosed by the sealant. With the first substrate 10 placed on the second substrate 20, the two substrates were hot-pressed to bond. An opening was created in the sealant. To prevent short-circuiting between the photosensitizer-supporting porous titanium oxide layer 3 and the second hole transport layer 6, a cellulose separator was inserted between the first substrate 10 and the second substrate 20.

A 10 mM solution of TEMPO in 1-ethyl-3-methylimidazolium TFSI was prepared as an electrolytic solution for the formation of a first hole transport layer 5. This electrolytic solution was injected through the opening, and the opening was closed using an ultraviolet-curable resin.

In this way, the photovoltaic device of Example 1 was obtained.

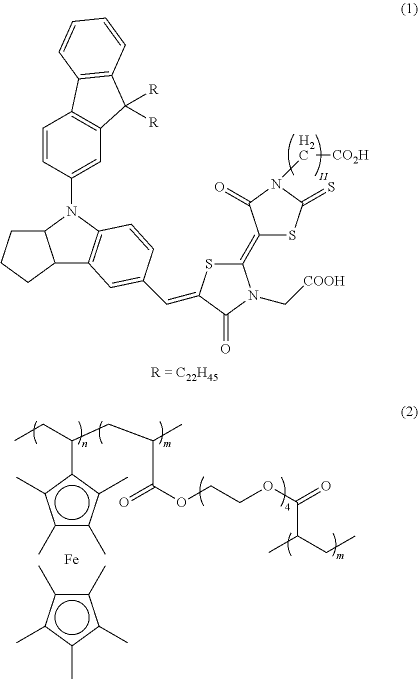

### Example 2

The TEMPO solution used as the first hole transport layer 5 was changed to a 10 mM solution of 2,2,6,6-tetramethyl-hydroxypiperidine 1-oxyl (TEMPOL) in 1-ethyl-3-methylimidazolium TFSI. The photovoltaic device of Example 2 was obtained in the same way as that of Example 1 except for this.

### Example 3

To obtain the photovoltaic device of Example 3, the TEMPO solution used as the first hole transport layer 5 in the fabrication of the photovoltaic device of Example 1 was changed to a solid layer of poly-4-methacryloyloxy-TEMPO (PTMA). The first hole transport layer 5 was formed by mixing 2 mg of PTMA, 8 mg of a carbon fiber material (Showa Denko) as a conductive agent, and 0.01 mg of PVDF as a binder with 0.1 ml of NMP and applying the resulting slurry to the porous titanium oxide layer 3 using drop casting.

### Example 4

In Example 4, a photovoltaic device having the same configuration as the photovoltaic device 101 in FIG. 2 was fabricated. This was achieved by adding a third hole transport layer 7 between the first hole transport layer 5 and the second hole transport layer 6 of the photovoltaic device of Example 1. The third hole transport layer 7 was formed by mixing 2 mg of polyvinylferrocene (PVFc), 8 mg of a carbon fiber material (Showa Denko), and 0.01 mg of PVDF with 0.1 ml of NMP and applying the resulting slurry to the PDMFc layer as the second hole transport layer 6 using drop casting.

### Example 5

A photovoltaic device having the same configuration as the photovoltaic device 300 in FIG. 4 was fabricated. The components used were as follows.
First electrode 1: Fluorine-doped SnO₂
Second electrode 2: Fluorine-doped SnO₂ and platinum
Photosensitizer: MD153 (Mitsubishi Paper Mills)
First redox substance: TEMPO
Second redox substance: PDMFc
Fourth redox substance: A quinone polymer

An electron accumulation layer 39 was formed on the first electrode 1, spaced from the porous titanium oxide layer 3. The photovoltaic device of Example 5 was fabricated in the same way as that of Example 1 except for this. The formation of the electron accumulation layer 39 was through the mixing of 2 mg of the quinone polymer represented by chemical formula (3), 8 mg of a carbon fiber material (Showa Denko) as a conductive agent, and 0.01 mg of PVDF as a binder with 0.1 ml of NMP and drop casting of the resulting slurry.

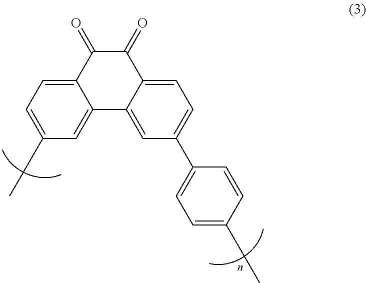 [SMILES: CCc1ccc(-c2ccc3c(c2)-c2cc(CC)ccc2C(=O)C3=O)cc1]

### Comparative Example 1

The formation of the second hole transport layer 6 on the second electrode 2 before bonding the first electrode 1 and the second electrode 2 was omitted. The photovoltaic device of Comparative Example 1 was fabricated in the same way as that of Example 1 except for this.

### Comparative Example 2

The redox substance in the second hole transport layer 6 was changed from PDMFc to PTMA. The photovoltaic device of Comparative Example 2 was fabricated in the same way as that of Example 1 except for this.

### Comparative Example 3

The redox substance in the second hole transport layer 6 was changed from PDMFc to PVFc. The photovoltaic device of Comparative Example 3 was fabricated in the same way as that of Example 1 except for this.

### Evaluation

### Measurement of Conversion Efficiency and Open-Circuit Voltage

The photovoltaic devices were illuminated with an illuminance of 200 lx using a fluorescent light, and the current-voltage profile was measured. After a steady current-voltage profile was reached, the conversion efficiency was measured. The illumination was then turned off, and the current-voltage profile was measured 1 minute later. The percentage retained voltage was determined as a proportion of the open-circuit voltage at 1 minute after the termination of illumination to that during illumination. It should be noted that this measurement condition, a brightness approximately 500 times smaller than that of sunlight, is not meant to restrict the applications of the devices. Naturally, photovoltaic devices according to the present disclosure can also be used under sunlight.

### Measurement of Potential Difference

The absolute potential of the redox substance in each of the hole transport layers was measured using an electrochemical assay with reference to Ag/Ag⁺ (an RE-7 reference electrode; BAS Inc.). Table 2 summarizes representative measured potentials. The difference between the redox potential of the first redox substance, contained in the first hole transport layer 5, and that of the second redox substance, contained in the second hole transport layer 6, for each photovoltaic device is presented under “Potential difference” in Table 1.

The method of measurement for liquid hole transport layers was as follows. The redox substance of interest and LiTFSI as a supporting salt were dissolved in acetonitrile. Two platinum electrodes for use as working and counter electrodes and an Ag/Ag⁺ reference electrode were put into the solution. Then cyclic voltammetry was performed using a potentiostat to determine the absolute potential of the redox substance.

The method of measurement for solid hole transport layers was as follows. A solution containing the redox substance of interest, a conductive agent, and a binder was applied to a working electrode. The resulting coating was heated and fired to remove the binder component, thereby fixing the redox substance on the working electrode. The working electrode was put into a solution of LiTFSI in acetonitrile together with counter and reference electrodes. Then cyclic voltammetry was performed using a potentiostat to determine the absolute potential of the redox substance.

It should be understood that although this series of measurements utilized LiTFSI as a supporting salt and acetonitrile as a solvent, usable salts and solvents are not limited to these.

TABLE 1

| | | | Redox material(s) in the first | | | Percentage |
|---|---|---|---|---|---|---|
| | | | hole transport layer 5 (/third | | | retained |
| | Hole transport layer | | hole transport layer 7)/ | Conversion | Potential | voltage at 1 |
| | composition | | second hole transport layer 6 | efficiency | difference | minute |
| Example 1 | Liquid/solid | 2 steps | TEMPO/PDMFc | 20% | 0.5 | 90% |
| Example 2 | Liquid/solid | 2 steps | TEMPOL/PDMFc | 12% | 0.56 | 90% |
| Example 3 | Solid/solid | 2 steps | PTMA/PDMFc | 8% | 0.6 | 90% |
| Example 4 | Liquid/solid/solid | 3 steps | TEMPO/PVFc/PDMFc | 20% | 0.5 | 90% |
| Example 5 | Liquid/solid (with | 2 steps | TEMPO/PDMFc | 20% | 0.5 | 90% |
| | an electron | | (and a quinone | | | |
| | accumulation | | polymer in the | | | |
| | layer) | | electron accumulation | | | |
| | | | layer 9) | | | |
| Comparative | Liquid | 1 step | TEMPO | 20% | — | 0% |
| Example 1 | | | | | | |
| Comparative | Liquid/solid | 2 steps | TEMPO/PTMA | 5% | −0.1 | 0% |
| Example 2 | | | | | | |
| Comparative | Liquid/solid | 2 steps | TEMPO/PVFc | 12% | 0.1 | 30% |
| Example 3 | | | | | | |

TABLE 2

| Redox material | Redox potential (vs. Ag/Ag+) | |
|---|---|---|
| PDMFc | ±0 | V |
| I₂ | +0.3 | V |
| PVFc | +0.4 | V |
| TEMPO | +0.5 | V |
| TEMPOL | +0.56 | V |
| PTMA | +0.6 | V |

The results summarized in Table 1 indicate that the photovoltaic devices of Examples 1 to 5 retained 90% of their initial voltage even at 1 minute after the termination of illumination. The photovoltaic devices of Comparative Examples 1 to 3 experienced voltage drops to 30% to 0% in 1 minute after the illumination was turned off.

As demonstrated herein, configurations in which the second redox substance, contained in the second hole transport layer 6, has a redox potential more negative than that of the first redox substance, contained in the first hole transport layer 5, by 0.5 V or more give the photovoltaic devices the capability of storing electricity. Such configurations are therefore effective in reducing voltage drops that occur in dark places.

What is claimed is:

1. A photovoltaic device comprising:
a first electrode;
a second electrode positioned to face the first electrode;
a porous titanium oxide layer on a surface of the first electrode facing the second electrode, the porous titanium oxide layer containing a porous titanium oxide supporting a photosensitizer;
a first hole transport layer between the porous titanium oxide layer and the second electrode, the first hole transport layer containing a first redox substance; and
a second hole transport layer between the first hole transport layer and the second electrode, the second hole transport layer containing a second redox substance, wherein
the second redox substance has a redox potential more negative than a redox potential of the first redox substance by 0.5 V or more.

2. The photovoltaic device according to claim 1, wherein the first hole transport layer is liquid.

3. The photovoltaic device according to claim 1, wherein the first redox substance is 2,2,6,6-tetramethylpiperidine 1-oxyl.

4. The photovoltaic device according to claim 1, wherein the redox potential of the second redox substance is in a range of −0.2 V to 0 V relative to an Ag/Ag⁺ electrode at 25° C.

5. The photovoltaic device according to claim 1, further comprising a third hole transport layer between the first and second hole transport layers, the third hole transport layer containing a third redox substance, wherein
the third redox substance has a redox potential more negative than the redox potential of the first redox substance and more positive than the redox potential of the second redox substance.

6. The photovoltaic device according to claim 1, further comprising:
a third electrode electrically connected to the first electrode; and
an electron accumulation layer in contact with the third electrode, the electron accumulation layer containing a fourth redox substance.

7. The photovoltaic device according to claim 1, further comprising an electron accumulation layer disposed on the surface of the first electrode and spaced from the porous titanium oxide layer, the electron accumulation layer containing a fourth redox substance.
